(19) United States
(12) Patent Application Publication
(10) Pub. No.: US 2022/0225530 A1
(43) Pub. Date: Jul. 14, 2022

(54) FAN ON PRINTED CIRCUIT BOARD

(71) Applicant: Intel Corporation, Santa Clara, CA (US)

(72) Inventors: Jeff Ku, Taipei (TW); Tongyan Zhai, Portland, OR (US); Lance Lin, New Taipei City (TW); Min Suet Lim, Gelugor (MY); Twan Sing Loo, Penang (MY)

(73) Assignee: Intel Corporation, Santa Clara, CA (US)

(21) Appl. No.: 17/699,513

(22) Filed: Mar. 21, 2022

(51) Int. Cl. H05K 7/20; H05K 1/02; G06F 1/20

(52) U.S. Cl. CPC H05K 7/20136; G06F 1/20; H05K 1/0203; H05K 7/20209

(57) ABSTRACT

Particular embodiments described herein provide for an electronic device that can be configured to include a support structure that includes a first side and an opposite second side. A first air mover can be coupled to the first side of the support structure, where a motor of the first air mover is on the support structure and an air mover controller where the air mover controller controls the first air mover through trace in the support structure. In some examples, a second air mover can be located on the second side of the support structure, where a motor of the second air mover is on the second side of the support structure and the second air mover is controlled by the air mover controller through trace in the support structure. The support structure can be a printed circuit board or motherboard.

### TECHNICAL FIELD

This disclosure relates in general to the field of computing and/or device cooling, and more particularly, to a fan on a printed circuit board.

### BACKGROUND

Emerging trends in electronic devices are changing the expected performance and form factor of devices as devices and systems are expected to increase performance and function while having a relatively thin profile. However, the increase in performance and/or function causes an increase in the thermal challenges of the devices and systems. For example, insufficient cooling can cause a reduction in device performance, a reduction in the lifetime of a device, and delays in data throughput.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIGS. 1A-1C are a simplified block diagram of a system to help enable a fan on a printed circuit board, in accordance with an embodiment of the present disclosure;

FIG. 2 is a simplified block diagram of a portion of a system to help enable a fan on a printed circuit board, in accordance with an embodiment of the present disclosure;

FIG. 3 is a simplified block diagram of a portion of a system to help enable a fan on a printed circuit board, in accordance with an embodiment of the present disclosure;

FIG. 4 is a simplified block diagram of a portion of a system to help enable a fan on a printed circuit board, in accordance with an embodiment of the present disclosure;

FIGS. 5A and 5B are simplified block diagrams of a portion of a system to help enable a fan on a printed circuit board, in accordance with an embodiment of the present disclosure;

FIG. 6 is a simplified block diagram perspective view of a portion of a system to help enable a fan on a printed circuit board, in accordance with an embodiment of the present disclosure;

FIG. 7 is a simplified block diagram of a portion of a system to help enable a fan on a printed circuit board, in accordance with an embodiment of the present disclosure;

FIG. 8 is a simplified block diagram of a portion of a system to help enable a fan on a fan board, in accordance with an embodiment of the present disclosure;

FIG. 9 is a simplified block diagram perspective view of a portion of a system to help enable a fan on a fan board, in accordance with an embodiment of the present disclosure;

FIG. 10 is a simplified block diagram side view of a portion of a system to help enable a fan on a fan board, in accordance with an embodiment of the present disclosure; and

FIG. 11 is a simplified block diagram of an electronic device that includes a fan on a printed circuit board, in accordance with an embodiment of the present disclosure.

The FIGURES of the drawings are not necessarily drawn to scale, as their dimensions can be varied considerably without departing from the scope of the present disclosure.

### DETAILED DESCRIPTION

The following detailed description sets forth examples of apparatuses, methods, and systems relating to enabling a fan on a printed circuit board (PCB). Features such as structure(s), function(s), and/or characteristic(s), for example, are described with reference to one embodiment as a matter of convenience; various embodiments may be implemented with any suitable one or more of the described features.

In an example, an electronic device can include a support structure, one or more air movers, and an air mover controller. The support structure can be a substrate and more particularly, a PCB. The one or more air movers can each be coupled to the support structure. More specifically, the one or more air movers can be a fan and the motor of the fan can be coupled to trace in the PCB. In some examples, if there are more than one air movers, one or more of the air movers can be a different type of fan (e.g., the first fan is a bladed fan and the second fan is a foam fan or some other type of fan). The support structure can include a first side and an opposite second side. In some examples, a first air mover is coupled to the first side of the support structure and a second air mover is coupled to the second side of the support structure. In other examples, a first air mover is coupled to the first side of the support structure and input/output (I/O) ports are coupled to the second side of the support structure under the area of the first air mover.

Some current fan designs require a fan cutout in the PCB to accommodate the fan casing and physically separate the fan from the PCB. By coupling the air mover to the PCB, the fan cutout can be eliminated. In addition, by coupling the air mover to the PCB, trace in the PCB can extend under the fan blades. Further, because there is no fan cutout, the I/O routing can be shorter as the I/O routing does not have to navigate around the fan cutouts. Also, the fan controller does not need to be inside the fan casing and can be located outside of the fan casing on the PCB. If there are more than one air mover, because the fan controller controls each air mover through trace in the PCB, each air mover can be independent controlled.

In some examples, one air mover can be coupled to the first side of the PCB and a second air mover can be coupled to the second side of the PCB. The first air mover and the second air mover can have the same or similar dimensions or may have different dimensions. Also, the first air mover may be a different type of air mover and/or have a different direction of rotation then the second air mover. In addition, by having one air mover coupled to the first side of the PCB and a second air mover can be coupled to the second side of the PCB, the system can also allow for a mixed hyperbaric fan design where exhaust air from the first air mover travels away from electronic components in the electronic device and exhaust air from the second air mover travels towards the electronic components in the electronic device. More specifically, an evacuative dual outlet fan can be located on a first side of the PCB over the PCB and a hyperbaric fan can be located on a second side of the PCB under the PCB

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials, and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

The terms “over,” “under,” “below,” “between,” and “on” as used herein refer to a relative position of one layer or component with respect to other layers or components. For example, one layer or component disposed on, over, or under another layer or component may be directly in contact with the other layer or component or may have one or more intervening layers or components. Moreover, one layer or component disposed between two layers or components may be directly in contact with the two layers or components or may have one or more intervening layers or components. In contrast, a first layer or first component “directly on” a second layer or second component is in direct contact with that second layer or second component. Similarly, unless explicitly stated otherwise, one feature disposed between two features may be in direct contact with the adjacent features or may have one or more intervening layers.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

Furthermore, the term “connected” may be used to describe a direct connection between the things that are connected, without any intermediary devices, while the term “coupled” may be used to describe either a direct connection between the things that are connected, or an indirect connection through one or more intermediary devices. The terms “substantially,” “close,” “approximately,” “near,” and “about,” generally refer to being within +/−20% of a target value based on the context of a particular value as described herein or as known in the art. For example, about one (1) mm would include one (1) mm and ±0.2 mm from one (1) mm. Similarly, terms indicating orientation of various elements (e.g., “coplanar,” “perpendicular,” “orthogonal,” “parallel,” or any other angle between the elements), generally refer to being within +/−5-20% of a target value based on the context of a particular value as described herein or as known in the art.

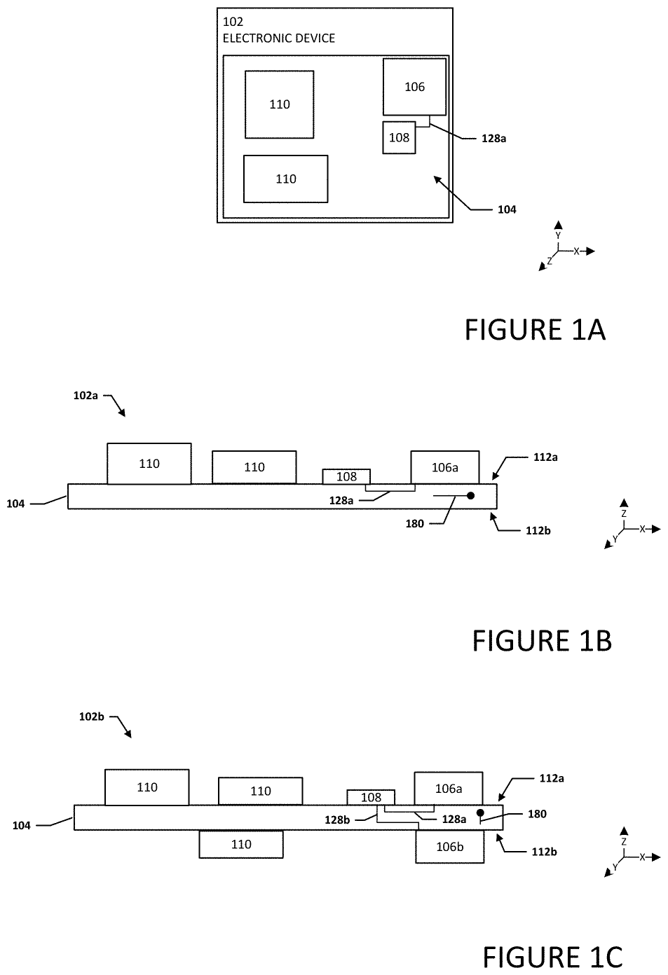

Turning to FIG. 1A, FIG. 1A is a simplified block diagram of an electronic device 102 configured with a fan on a PCB, in accordance with an embodiment of the present disclosure. In an example, the electronic device 102 can include a support structure 104, an air mover 106, an air mover controller 108, and one or more electronic components 110. The support structure 104 can be a substrate and more particularly, a PCB. In some examples, the support structure 104 is a motherboard, mainboard, or main PCB for the electronic device 102. The air mover 106 can be a fan and the motor of the fan can be coupled to the support structure 104. In a specific example, the air mover 106 is a fan and the motor of the fan is coupled to air mover trace 128a in the support structure 104. The air mover controller 108 can activate and deactivate the air mover 106 and control the speed of the air mover 106 using the air mover trace 128a in the support structure 104. Each of the electronic components 110 can be a device or group of devices available to assist in the operation or function of the electronic device 102. In addition, one or more of the electronic components 110 is a heat source (e.g., processor, logic unit, field programmable gate array (FPGA), chip set, integrated circuit (IC), a graphics processor, graphics card, battery, memory, or some other type of heat generating device). In an example, an electronic component 110 may be a central processing unit of the electronic device 102.

Turning to FIG. 1B, FIG. 1B is a simplified block diagram of an electronic device 102a configured with a fan on a PCB, in accordance with an embodiment of the present disclosure. In an example, the electronic device 102a can include the support structure 104, an air mover 106a, the air mover controller 108, and the one or more electronic components 110. The support structure 104 can be a substrate and more particularly, a PCB. In some examples, the support structure 104 is a motherboard, mainboard, or main PCB for the electronic device 102a. The support structure 104 can include a first side 112a, a second side 112b, and component trace 180. The first side 112a of the support structure 104 is opposite the second side 112b of the support structure 104. As illustrated in FIG. 1B, the air mover 106a is coupled to the first side 112a of the support structure 104. The air mover 106a can be a fan and the motor of the fan can be coupled to the support structure 104. In a specific example, the air mover 106a is a fan and the motor of the fan is coupled to trace in the support structure 104. The air mover controller 108 can activate and deactivate the air mover 106a and control the speed of the air mover 106a using the air mover trace 128a in the support structure 104. In some examples, a portion of the component trace 180 can be located in the support structure 104 under the area of the air mover 106a (under the blades of the air mover 106a). The component trace 180 can connect two or more of the electronic components to each other.

Turning to FIG. 1C, FIG. 1C is a simplified block diagram of an electronic device 102b configured with a fan on a PCB, in accordance with an embodiment of the present disclosure. In an example, the electronic device 102b can include the support structure 104, the air mover 106a, an air mover 106b, the air mover controller 108, and the one or more electronic components 110. The support structure 104 can be a substrate and more particularly, a PCB. In some examples, the support structure 104 is a motherboard, mainboard, or main PCB for the electronic device 102b. The support structure 104 can include the first side 112a, the second side 112b, and the component trace 180. The first side 112a of the support structure 104 is opposite the second side 112b of the support structure 104. As illustrated in FIG. 1C, the air mover 106a is coupled to the first side 112a of the support structure 104 and the air mover 106b is coupled to the second side 122b of the support structure 104.

The air mover 106a can be a fan and the motor of the fan can be coupled to the support structure 104. In a specific example, the air mover 106a is a fan and the motor of the fan is coupled to the air mover trace 128a in the support structure 104. The air mover 106b can be a fan and the motor of the fan can be coupled to the support structure 104. In a specific example, the air mover 106b is a fan and the motor of the fan is coupled to air mover trace 128b in the support structure 104. The air mover controller 108 can independently activate and deactivate the air mover 106a using the air mover trace 128a in the support structure 104 and the air mover 106b and independently control the speed of the air mover 106a and the air mover 106b using the air mover trace 128b in the support structure 104.

Some current electronic devices have a fan cutout in the PCB to accommodate the fan for the electronic device. The main problem with such a design is that the fan cutouts can occupy a significant portion of the PCB and can cause difficulties with the design layout of components and trace on the PCB. In addition, high speed input/output (HSIO) routing requires a wraparound at the fan cutout causing longer HSIO routing path.

In the electronic device 102, the air mover 106a (and the air mover 106b if present) can be coupled to the support structure 104. By coupling the air mover 106a (and the air mover 106b if present) to the support structure 104, the requirement of having a fan cutout can be eliminated. Eliminating the need for a fan cutout can help increase the available space on the PCB for components and trace. In addition, by eliminating the fan cutout, HSIO routing can be simplified as the routing does not need to wraparound a fan cutout.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur. Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment.

It is to be understood that other embodiments may be utilized and structural changes may be made without departing from the scope of the present disclosure. Substantial flexibility is provided in that any suitable arrangements and configuration may be provided without departing from the teachings of the present disclosure.

For purposes of illustrating certain example techniques, the following foundational information may be viewed as a basis from which the present disclosure may be properly explained. End users have more media and communications choices than ever before. A number of prominent technological trends are currently afoot (e.g., more computing elements, more online video services, more Internet traffic, more complex processing, etc.), and these trends are changing the expected performance and form factor of devices as devices and systems are expected to increase performance and function while having a relatively thin profile. However, the increase in performance and/or function causes an increase in the thermal challenges of the devices and systems. For example, in some devices, it can be difficult to cool a particular heat source. One way to cool a heat source is to use a fan.

Currently, the fan is becoming one of the most critical parts in modern laptops and often occupies the largest system space after the PCB and battery or batteries. The fan height, size, and the number of fans is proportion to the fan's performance. In high performance systems, larger fans are used to help mitigate the increased heat generated by the high performance systems. Due to the increase heat generated by high performance systems, the high performance systems require a larger fan size and/or an increased number of fans (as compared to systems with a lower performance) to help dissipate the heat.

To accommodate the fan, a portion of the PCB must be removed where the fan will be located. The portion that is removed is often call the fan cutout. The fan cutouts can create difficulties in the arrangement of components and trace on the PCB to achieve effective panelization utilization and can increase the overall cost of the PCB. In some systems, the fan cutout can occupy about thirty percent (30%) of raw PCB area. With this area unable to be used for component placement and routing, this creates wastage of PCB materials.

Also, HSIO routing requires a wraparound at the fan cutout causing a longer HSIO routing path. In some systems, the longer HSIO routing path can cause the requirement of added retimers (a mixed signal analog/digital device that is protocol-aware and has the ability to fully recover data, extract the embedded dock, and retransmit a fresh copy of the data using a dean dock). Each added retimer drives up the cost and complexity of the system. In addition, for high performance systems that require large and/or multiple fans at the edges of the chassis, I/O ports are unable to be placed as side ports because the space is occupied by the fan and/or the fan cutout. These systems can provide better cooling capability compared to some current systems, however, only rear I/O ports are available. Having only rear I/O ports can retime compromise the user experience and it is not intuitive because rear I/O ports can be more difficult for users to access as compared to side I/O ports. Currently, there is a need to allow a fan to be coupled to an electronic device's PCB such that the PCB does not need a fan cutout.

A system to enable a fan on a PCB, as outlined in FIGS. 1A-1C, can resolve these issues (and others). In an example, the system can include an air mover with a motor on the PCB. More specifically, a fan's motor can be coupled to an electronic device's PCB. The integration of the fan's motor onto the PCB helps to remove the need of a relatively large fan cutout on the PCB and can shorten the HSIO routing length. In addition, the side I/O port placement limitation is also addressed because the fan cutout is not needed. Also, the integration of the fan's motor into the PCB can help make fan placement more flexible without compromises on the system's performance. In an example, the motor for the fan is mounted to the PCB with motor pins at each side as a guide to insert into the PCB. The fan position can be held in place after the PCB passes through surface mount technology (SMT), dual in-line package (DIP) like connectors, or some other type of connectors.

In an example, the system can allow for a disaggregated fan design while integrating fan structures into the PCB to help eliminate the fan cutouts on the PCB. In some examples, one or more fans are mounted on the PCB with the motor and the fan motor controller integrated (SMT, DIP, etc.) into the PCB. As compared to some current fan designs, the fan cable, connector pairs, and driver IC count could be eliminated for cost reduction.

More specifically, instead of applying a single relatively thick fan (e.g., about 9 mm fan) as in some conventional system designs, the system can include two thin fans (e.g., with a combined thickness equal to or less than about 9 mm) equivalent to a thick fan without degrading the system performance. Smaller fans can deliver a higher static pressure and a relatively better operating flow rate despite the reduced size. The system can allow for a disaggregated board fan design by splitting a single fan to a double deck fan with a first fan on a first side of the PCB and a second fan on a second side of the PCB opposite the first side of the PCB. In addition, flexibility of fan placement on the PCB can be created by integrating the fan motor and the motor controller onto the PCB without the need of a fan cutout area.

If two fans are used, the system can also allow for a mixed hyperbaric fan design. More specifically, an evacuative dual outlet fan can be located on a first side of the PCB over the PCB and a hyperbaric fan can be located on a second side of the PCB under the PCB. In addition, the system can allow I/O side ports placement in the same area on the PCB as the fan. More specifically, a fan can be located on the first side of the PCB over the PCB and I/O side ports can be located on the second side of the PCB, under the PCB and in the same general area as the fan. Note that the terms “over” and “under” are relative terms depending on the orientation of the electronic device.

The air mover coupled to the PCB can help allow for better signal integrity with shorter HSIO length by eliminating the need for the HSIO routing to wraparound a fan cutout outline. In addition, the air mover coupled to the PCB can allow for a relatively larger battery in the system (as compared to similarly sized systems with a fan cutout) to help provide an increased battery life with an additional PCB width reduction without required a routing channel below a fan cutout. Also, the fan coupled to the PCB can help provide a better user experience without I/O side ports placement tradeoffs when the fan count is increased. Further, the fan coupled to the PCB can allow for flexibility of the PCB and fan placement closer to one or more heat sources without degrading the system performance. In addition, upper deck fans (e.g., fans on a first side of the PCB) and lower deck fans (e.g., fans on an opposite second side of the PCB) could be designed with different sizes, types, and flow architectures. Fan sizes could also be larger without reserving the gaps between the fans and PCB that are used to accommodate tolerances in the fan casing of current fan designs. Also, the fan coupled to the PCB can allow for reduced BOM cost through improved PCB panelization, reduced number of retimers, and elimination of HSIO cables/connectors. In addition, the fan coupled to the PCB can allow for power saving and acoustic control with intelligent fan speed control (IFSC) features through a disaggregated fan design. More specifically, upper deck fans (e.g., fans on a first side of the PCB) and lower deck fans (e.g., fans on an opposite second side of the PCB) can be independently activated (ON/OFF) or controlled separately according to different scenarios/workloads. For light workload, lower deck fans only could be activated as they are under the PCB and would generate less perceived noise by the user. Upper deck fans could be activated when the workload is higher and requires more air flow to cool the system. Also, the speed of each fan can be independently controlled.

In an example, the system can include a mixed hyperbaric fan design with an evacuative dual outlet fan placed on the PCB and a hyperbaric fan placed under the PCB. The upper evacuative dual outlet fan can have one or more heat exchangers (e.g., two rows of heat exchangers) in front of its two outlets and the lower deck fan can have a row of heat exchanger in front of its rear outlet while the other outlet blows air into the chassis. With such a design, the edge of the PCB that is without a heat exchanger could be used for placing I/O connecters without any conflicts with side heat exchangers.

In an example implementation, the electronic device 102, is meant to encompass a computer, a personal digital assistant (PDA), a laptop or electronic notebook, a cellular telephone, an iPhone, a tablet, an IP phone, network elements, network appliances, servers, routers, switches, gateways, bridges, load balancers, processors, modules, or any other device, component, element, or object that includes at least one air mover or fan and a support structure (e.g., a PCB). The electronic device 102 may include any suitable hardware, software, components, modules, or objects that facilitate the operations thereof, as well as suitable interfaces for receiving, transmitting, and/or otherwise communicating data or information in a network environment. This may be inclusive of appropriate algorithms and communication protocols that allow for the effective exchange of data or information. The electronic device 102 may include virtual elements.

In regards to the internal structure, the electronic device 102 can include memory elements for storing information to be used in operations. The electronic device 102 may keep information in any suitable memory element (e.g., random access memory (RAM), read-only memory (ROM), erasable programmable ROM (EPROM), electrically erasable programmable ROM (EEPROM), application specific integrated circuit (ASIC), etc.), software, hardware, firmware, or in any other suitable component, device, element, or object where appropriate and based on particular needs. Any of the memory items discussed herein should be construed as being encompassed within the broad term ‘memory element.’ Moreover, the information being used, tracked, sent, or received could be provided in any database, register, queue, table, cache, control list, or other storage structure, all of which can be referenced at any suitable timeframe. Any such storage options may also be included within the broad term ‘memory element’ as used herein.

In certain example implementations, functions may be implemented by logic encoded in one or more tangible media (e.g., embedded logic provided in an ASIC, digital signal processor (DSP) instructions, software (potentially inclusive of object code and source code) to be executed by a processor, or other similar machine, etc.), which may be inclusive of non-transitory computer-readable media. In some of these instances, memory elements can store data used for operations described herein. This includes the memory elements being able to store software, logic, code, or processor instructions that are executed to carry out activities or operations.

Additionally, the air mover controller 108 and one or more of the electronic components 110 may include one or more processors that can execute software or an algorithm. In one example, the processors can transform an element or an article (e.g., data) from one state or thing to another state or thing. In another example, activities may be implemented with fixed logic or programmable logic (e.g., software/computer instructions executed by a processor) and the air mover controller 108 and one or more of the electronic components 110 identified herein could be some type of a programmable processor, programmable digital logic (e.g., a field programmable gate array (FPGA), an erasable programmable read-only memory (EPROM), an electrically erasable programmable read-only memory (EEPROM)) or an ASIC that includes digital logic, software, code, electronic instructions, or any suitable combination thereof. Any of the potential processing elements, modules, and machines described herein should be construed as being encompassed within the broad term ‘processor.’

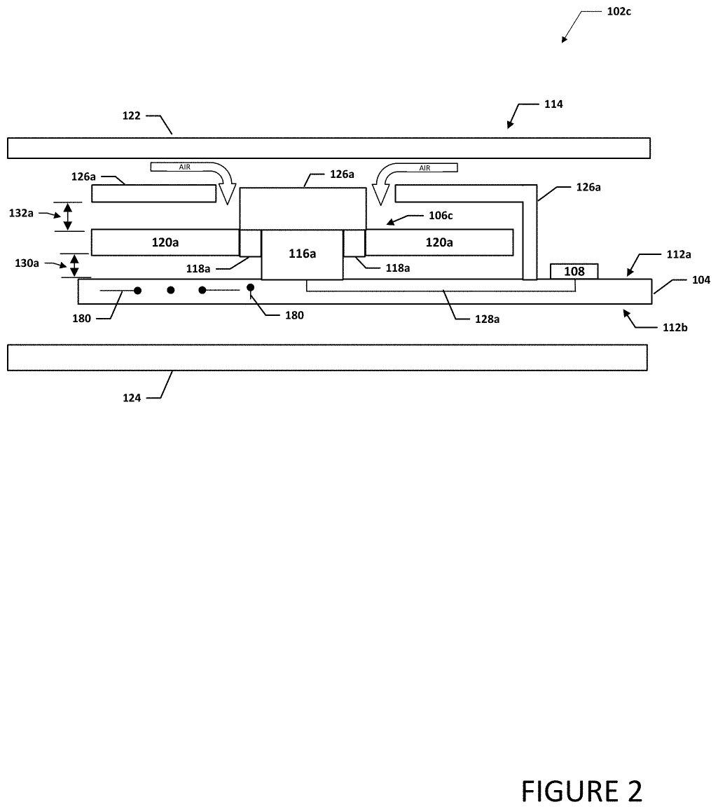

Turning to FIG. 2, FIG. 2 is a simplified block diagram of a portion of an electronic device 102c, in accordance with an embodiment of the present disclosure. In an example, the electronic device 102c can include the support structure 104, an air mover 106c, the air mover controller 108, and a chassis 114. The support structure 104 can include the first side 112a, the second side 112b, and the component trace 120. The air mover 106c can include a fan motor 116a, magnets 118a, and fan blades 120a. The chassis 114 can include a first portion of the chassis 122 and a second portion of the chassis 124. In an example, a fan casing 126a can enclose at least a portion of the air mover 106c to help protect the air mover 106c. The fan casing 126a can have gaps to allow air to enter the fan casing 126c and travel to the fan blades 120a.

In an example, as illustrated in FIG. 2, the fan motor 116a is coupled to the support structure 104 and the air mover controller 108 is coupled to the support structure 104. The air mover controller 108 can control the fan motor 116a using the air mover trace 128a in the support structure 104. Because the air mover controller 108 can control the fan motor 116a using the air mover trace 128a in the support structure 104, the air mover controller 108 can be located inside the fan casing 126a or outside of the fan casing 126a, depending on design choice and design constraints.

The fan blades 120a can be over the support structure 104 a blade to support structure distance 130a. In an example, the blade to support structure distance 130a may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to support structure distance 130a is less than or equal to about 1.5 millimeters. In another specific example, the blade to support structure distance 130a may be about 0.6 millimeters.

The fan casing 126a can be over the fan blades 120a a blade to fan casing distance 132a. In an example, the blade to fan casing distance 132a may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to fan casing distance 132a is less than or equal to about 1.5 millimeters. In another specific example, the blade to fan casing distance 132a may be about 0.9 millimeters. Note that the number and dimensions of the air movers depends on design choice and design constraints and a different number and/or dimension of the air movers may be used than what is illustrated in FIG. 2 and/or described above.

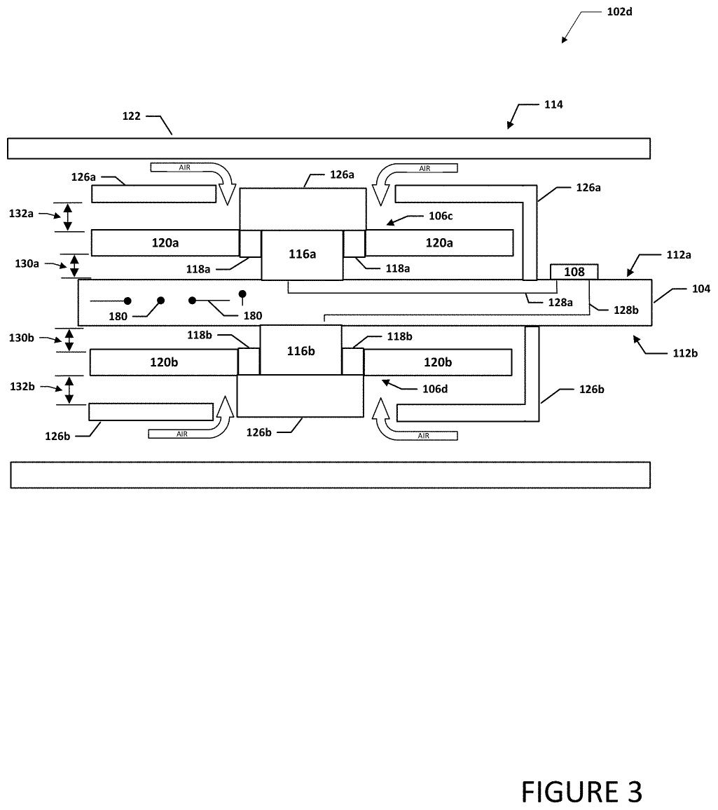

Turning to FIG. 3, FIG. 3 is a simplified block diagram of a portion of an electronic device 102d, in accordance with an embodiment of the present disclosure. In an example, the electronic device 102d can include the support structure 104, the air mover 106c, an air mover 106d, the air mover controller 108, and the chassis 114. The support structure 104 can include the first side 112a, the second side 112b, and component trace 180. The air mover 106c can include the fan motor 116a, the magnets 118a, and the fan blades 120a. The air mover 106d can include a fan motor 116b, magnets 118b, and fan blades 120b. The chassis 114 can include the first portion of the chassis 122 and the second portion of the chassis 124. In an example, the fan casing 126a can enclose at least a portion of the air mover 106c to help protect the air mover 106c. The fan casing 126a can have gaps to allow air to enter the fan casing 126a and travel to the fan blades 120a. Also, a fan casing 126b can enclose at least a portion of the air mover 106d to help protect the air mover 106d. The fan casing 126b can have gaps to allow air to enter the fan casing 126b and travel to the fan blades 120b.

In an example, as illustrated in FIG. 3, the fan motor 116a is coupled to the support structure 104, the fan motor 116b is coupled to the support structure 104, and the air mover controller 108 is coupled to the support structure 104. The air mover controller 108 can control the fan motor 116a using air mover trace 128a in the support structure 104 and can control the fan motor 116b using air mover trace 128b in the support structure 104. Because the air mover controller 108 can control the fan motor 116a using air mover trace 128a in the support structure 104 and can control the fan motor 116b using air mover trace 128b in the support structure 104, the air mover controller 108 can be located inside the fan casing 126a, inside the fan casing 126b, or outside of the fan casing 126a and the fan casing 126b, depending on design choice and design constraints. In addition, the air mover controller 108 can use the air mover trace 128a to independently control the fan motor 116a and can use the air mover trace 128b to independently control the fan motor 116b.

The fan blades 120a can be over the support structure 104 the blade to support structure distance 130a. In an example, the blade to support structure distance 130a may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to support structure distance 130a is less than or equal to about 1.5 millimeters. In another specific example, the blade to support structure distance 130a may be about 0.6 millimeters. Also, the fan blades 120b can be under the support structure 104 a blade to support structure distance 130b. In an example, the blade to support structure distance 130b may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to support structure distance 130b is less than or equal to about 1.5 millimeters. In another specific example, the blade to support structure distance 130b may be about 0.6 millimeters. The blade to support structure distance 130a and the blade to support structure distance 130b may be the same or similar or the blade to support structure distance 130a and the blade to support structure distance 130b may be different.

In addition, the fan casing 126a can be over the fan blades 120a the blade to fan casing distance 132a. In an example, the blade to fan casing distance 132a may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to fan casing distance 132a is less than or equal to about 1.5 millimeters. In another specific example, the blade to fan casing distance 132a may be about 0.9 millimeters. Also, the fan casing 126b can be under the fan blades 120b the blade to fan casing distance 132b. In an example, the blade to fan casing distance 132b may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to fan casing distance 132b is less than or equal to about 1.5 millimeters. In another specific example, the blade to fan casing distance 132b may be about 0.9 millimeters. The blade to fan casing distance 132a and the blade to fan casing distance 132b may be the same or similar or the blade to fan casing distance 132a and the blade to fan casing distance 132b may be different. Note that the number and dimensions of the air movers depends on design choice and design constraints and a different number of the air movers may be used than what is illustrated in FIG. 3. Also, each of the air movers can have similar dimensions or different dimensions depending on design choice and design constraints.

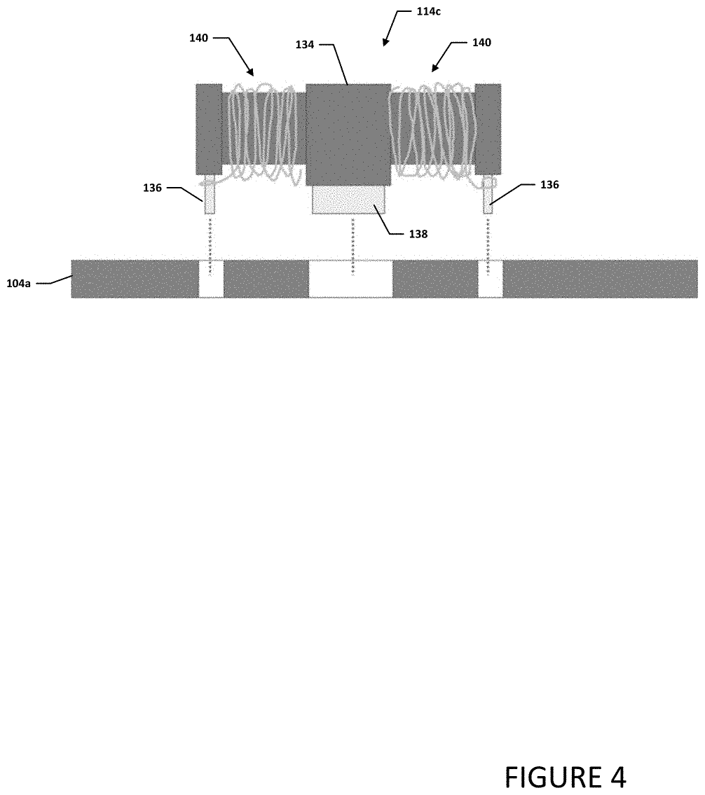

Turning to FIG. 4, FIG. 4 is a simplified block diagram of a portion of a motor 114c, in accordance with an embodiment of the present disclosure. As illustrated in FIG. 4, the motor 114c can include a stator 134, coil pins 136, motor shaft pin 138, and motor windings 140. The motor 114c, or more specifically, the motor shaft pin 138 can be coupled to the support structure 104a with the motor shaft pins 138 at each side to act as a guide to help insert the motor shaft pin 138 into the support structure 104a. The motor 114c position will be held in place after the support structure 104a passes through SMT or DIP like connectors. With the motor 114c coupled to and/or integrated into the support structure 104a, the cable, connector pairs, and driver IC count of current fans can be eliminated because the motor can be controlled using traces in the support structure 104a.

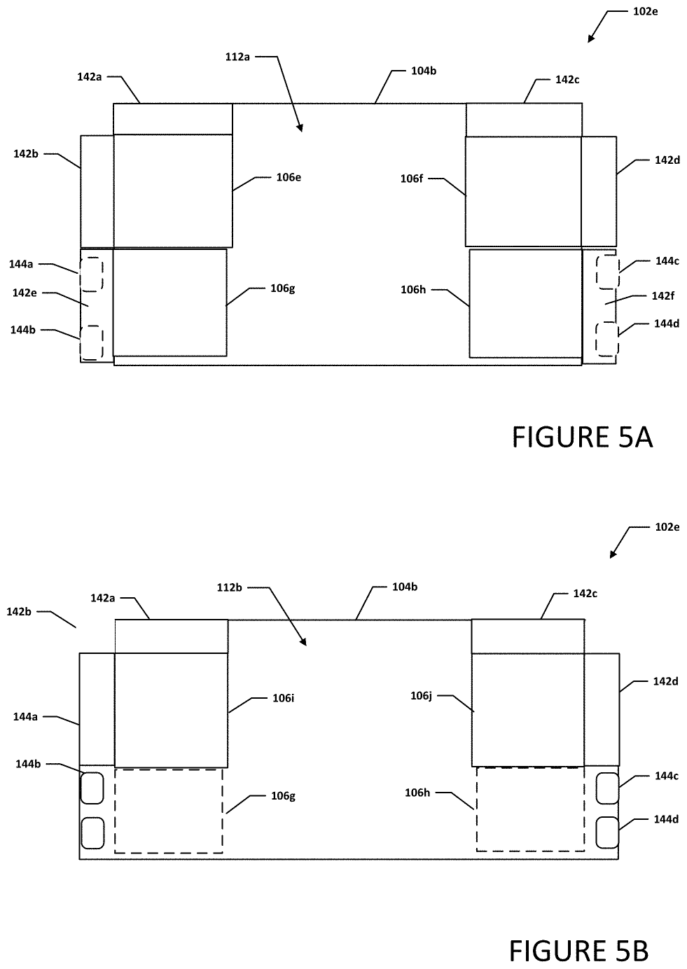

Turning to FIG. 5A, FIG. 5A is a simplified block diagram of a top view of a portion of an electronic device 102e, in accordance with an embodiment of the present disclosure. In an example, the electronic device 102e can include a support structure, a plurality of air movers, a plurality of heat exchangers, and one or more I/O ports. More specifically, as illustrated in FIG. 5A, the electronic device 102e can include a support structure 104b, air movers 106e-106j, heat exchangers 142a-142f, and I/O ports 144a-144d. The support structure 104b can include the first side 112a and the second side 112b (shown in FIG. 5B). Each of the air movers 106e-106h can be located on the first side 112a of the support structure 104b. One or more of the heat exchangers 142a-142f can be fins. Each of the one or more of the heat exchangers 142a-142f can be located near an exhaust of an air mover. For example, the heat exchangers 142a and 142b can be located near an exhaust of the air mover 106e, the heat exchangers 142c and 142d can be located near an exhaust of the air mover 106f, the heat exchanger 142e can be located near an exhaust of the air mover 106g, and the heat exchanger 142f can be located near an exhaust of the air mover 106h.

Turning to FIG. 5B, FIG. 5B is a simplified block diagram of a bottom view of a portion of the electronic device 102e, in accordance with an embodiment of the present disclosure. As illustrated in FIG. 5B, the electronic device 102e can include the support structure 104b and the support structure 104b can include the first side 112a (shown in FIG. 5A) and the second side 112b. Air movers 106i and 106j can be located on the second side 112b of the support structure 104b. One or more of the heat exchangers 142a-142f can be fins located near an exhaust of an air mover. For example, the heat exchangers 142a and 142b can be located near an exhaust of the air mover 106i and the heat exchangers 142c and 142d can be located near an exhaust of the air mover 106j. The I/O ports 144a-144d can be located on the second side 112b under an air mover. More specifically, the I/O ports 144a and 114b can be located on the second side 112b under the air mover 106g (illustrated in FIG. 5A on the first side 112a) and the I/O ports 144c and 144d can be located on the second side 112b under the air mover 106h (illustrated in FIG. 5A on the first side 112a). Note that the number and dimensions of the air movers and I/O ports depends on design choice and design constraints and a different number of the air movers and/or I/O ports may be used than what is illustrated in FIGS. 5A and 5B. Also, each of the air movers can have similar dimensions or different dimensions depending on design choice and design constraints.

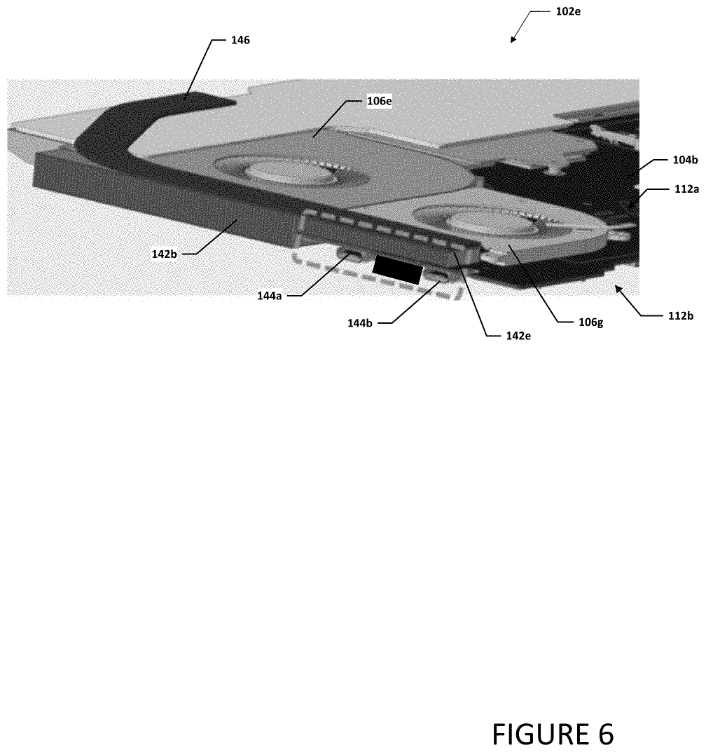

Turning to FIG. 6, FIG. 6 is a simplified block diagram of a portion of the electronic device 102e, in accordance with an embodiment of the present disclosure. As illustrated in FIG. 6, the electronic device 102e can include the support structure 104b, the air movers 106e and 106g, the heat exchangers 142b and 142e, and the I/O ports 144a and 144b. The support structure 104b can include the first side 112a and the second side 112b. Each of the air movers 106e and 106g can be located on the first side 112a of the support structure 104b. The heat exchanger 142b can be located near an exhaust of the air mover 106e and the heat exchanger 142e can be located near an exhaust of the air mover 106g. The I/O ports 144a-144d can be located on the second side 112b under the air mover 106g. Note that the number and dimensions of the air movers and I/O ports depends on design choice and design constraints and a different number of the air movers and/or I/O ports may be used than what is illustrated in FIG. 6. Also, each of the air movers can have similar dimensions or different dimensions depending on design choice and design constraints.

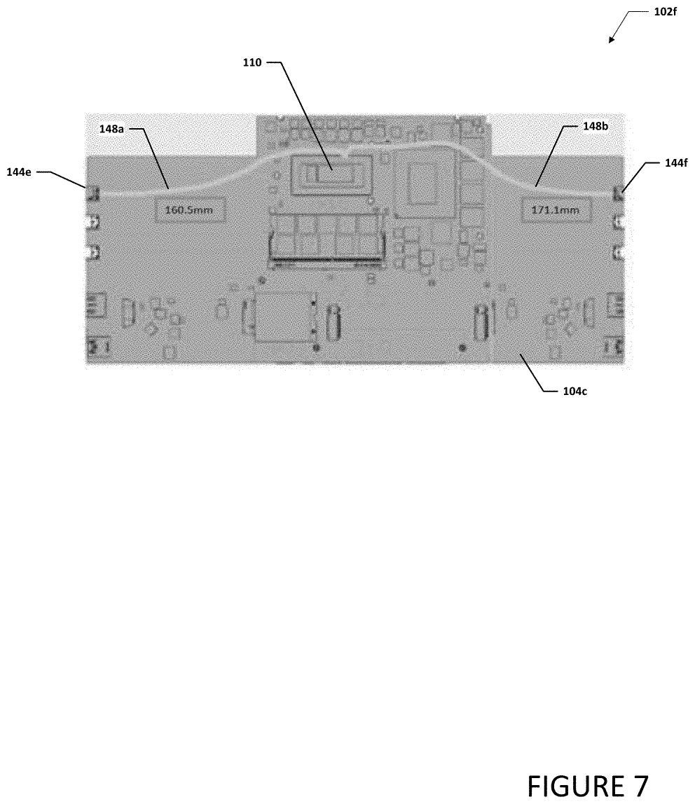

Turning to FIG. 7, FIG. 7 is a simplified block diagram of a portion of an electronic device 102f, in accordance with an embodiment of the present disclosure. In an example, the electronic device 102f can include a support structure 104c and one or more I/O ports. For example, as illustrated in FIG. 7, the electronic device includes I/O ports 144e and 144f. The I/O ports 144e and 144f can be in communication with an electronic component 110 using HSIO connection lines 148a and 148b. More specifically, the I/O port 144e can be in communication with the electronic component 110 using the HSIO connection line 148a and the I/O port 144f can be in communication with the electronic component 110 using the HSIO line 148b. The electronic component 110 can be a processor or some other electronic component 110 in communication with I/O port 144e and/or I/O port 144f using one or more HSIO connections. Each of the HSIO connection lines 148a and 148b can be a high speed signal trace. As illustrated in FIG. 7, the HSIO connection lines 148a and 148b do not need to accommodate fan cutouts in the support structure 104f.

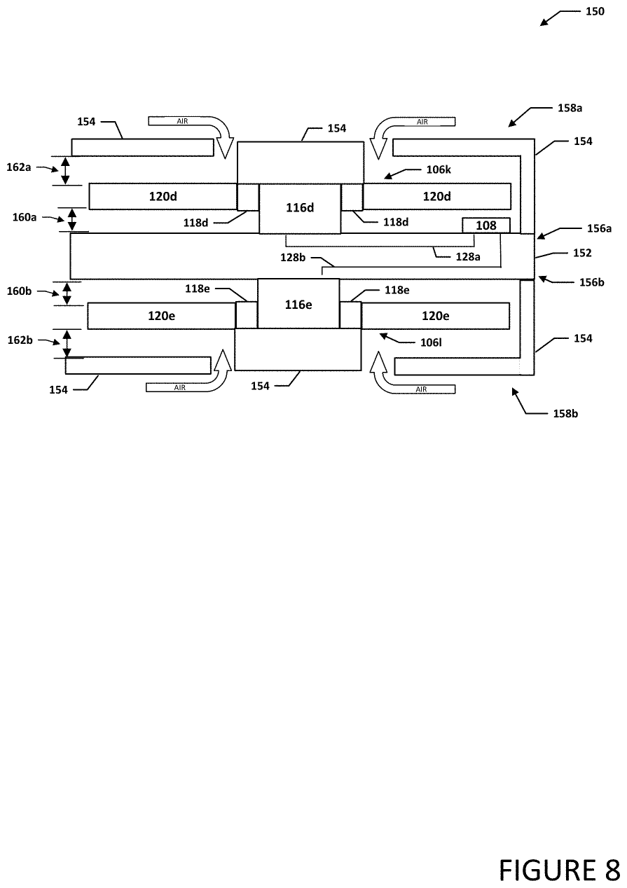

Turning to FIG. 8, FIG. 8 is a simplified block diagram of a portion of a fan 150, in accordance with an embodiment of the present disclosure. In an example, the fan 150 can include one or more air movers, a fan support structure, and a fan cover. More specifically, as illustrated in FIG. 8, the fan 150 can include air movers 106k and 106l, a fan support structure 152, and a fan cover 154. The fan support structure 152 can include a first side 156a and a second side 156b.

The air mover 106k can include a fan motor 116d, magnets 118d, and fan blades 120d. The air mover 106l can include a fan motor 116e, magnets 118d, and fan blades 120d. In an example, the fan cover 154 can enclose at least a portion of the air mover 106k and the air mover 106l to help protect the air mover 106k and the air mover 106l. In some examples, the fan support structure 152 extends through the fan cover 154 to create a first portion fan cover 158a and a second portion fan cover 158b. The fan cover 154 can have gaps to allow air to enter the fan cover 154 and travel to the fan blades 120d and the fan blades 120e.

In an example, as illustrated in FIG. 8, the fan motor 116d is coupled to the fan support structure 152, the fan motor 116e is coupled to the fan support structure 152, and the air mover controller 108 is coupled to the fan support structure 152. The air mover controller 108 can control the fan motor 116da using air mover trace 128a in the fan support structure 152 and can control the fan motor 116e using air mover trace 128b in the fan support structure 152. Because the air mover controller 108 can control the fan motor 116d using air mover trace 128a in the fan support structure 152 and can control the fan motor 116e using air mover trace 128b in the fan support structure 152, the air mover controller 108 can be located inside the fan cover 154 or outside of the fan cover 154 if the fan support structure 152 extends outside of the fan cover 154, depending on design choice and design constraints. In addition, the air mover controller 108 can use the air mover trace 128a to independently control the fan motor 116d and can use the air mover trace 128b to independently control the fan motor 116e.

The fan blades 120d can be over the fan support structure 152 a blade to fan support structure distance 160a. In an example, the blade to fan support structure distance 160a may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to fan support structure distance 160a is less than or equal to about 1.5 millimeters. In another specific example, the blade to fan support structure distance 160a may be about 0.6 millimeters. Also, the fan blades 120e can be under the fan support structure 152 a blade to fan support structure distance 160b. In an example, the blade to fan support structure distance 160b may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to fan support structure distance 160b is less than or equal to about 1.5 millimeters. In another specific example, the blade to fan support structure distance 160b may be about 0.6 millimeters. The blade to fan support structure distance 160a and the blade to fan support structure distance 160b may be the same or similar or the blade to fan support structure distance 160a and the blade to fan support structure distance 160b may be different.

In addition, the fan cover 154 (or first portion fan cover 158a) can be over the fan blades 120d a blade to fan cover distance 162a. In an example, the blade to fan cover distance 162a may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to fan cover distance 162a is less than or equal to about 1.5 millimeters. In another specific example, the blade to fan cover distance 162a may be about 0.9 millimeters. Also, the fan cover 154 (or second portion fan cover 158b) can be under the fan blades 120e a blade to fan cover distance 162b. In an example, the blade to fan cover distance 162b may be between about two (2) millimeters and about 0.20 millimeters and ranges therein (e.g., between about one (1) and about 0.5 millimeters, or between about 1.5. and about 0.8 millimeters), depending on design choice and design constraints. In a specific example, the blade to fan cover distance 162b is less than or equal to about 1.5 millimeters. In another specific example, the blade to fan cover distance 162b may be about 0.9 millimeters. The blade to fan cover distance 162a and the blade to fan cover distance 162b may be the same or similar or the blade to fan cover distance 162a and the blade to fan cover distance 162b may be different. Note that the number and dimensions of the air movers depends on design choice and design constraints and a different number of the air movers may be used than what is illustrated in FIG. 8. Also, each of the air movers can have similar dimensions or different dimensions depending on design choice and design constraints.

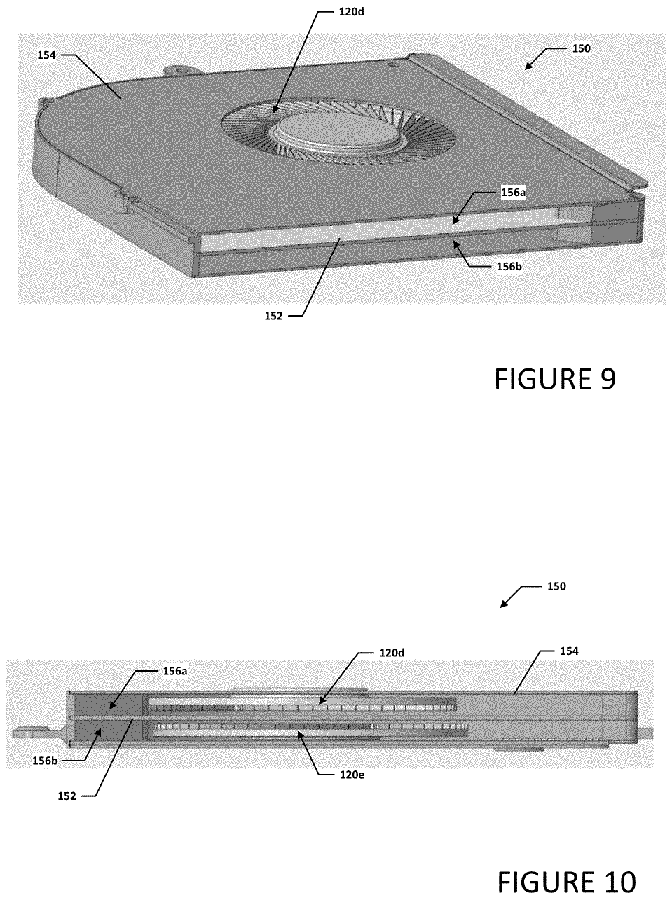

Turning to FIG. 9, FIG. 9 is a simplified perspective block diagram of a portion of the fan 150, in accordance with an embodiment of the present disclosure. In an example, the fan 150 can include one or more air movers (not shown), the fan support structure 152, and the fan cover 154. The fan support structure 152 can include the first side 156a and the second side 156b. Each of the one or more air movers can include a fan motor, magnets, and fan blades. For example, as illustrate in FIG. 9, one of the air movers (e.g., the air mover 106k) includes fan blades 120d. The fan cover 154 can enclose at least a portion of each of the one or more air movers to help protect the one or more air movers. The fan cover 154 can have gaps to allow air to enter the fan cover 154 and travel to the fan blades 120d.

Turning to FIG. 10, FIG. 10 is a simplified perspective block diagram of a portion of the fan 150, in accordance with an embodiment of the present disclosure. In an example, the fan 150 can include one or more air movers (not referenced), the fan support structure 152, and the fan cover 154. The fan support structure 152 can include the first side 156a and the second side 156b. Each of the one or more air movers can include a fan motor, magnets, and fan blades. For example, as illustrate in FIG. 10, one of the air movers (e.g., the air mover 106k) includes fan blades 120d and a second air mover (e.g., the air mover 106l) includes fan blades 120e. The fan cover 154 can enclose at least a portion of each of the one or more air movers to help protect the one or more air movers. The fan cover 154 can have gaps to allow air to enter the fan cover 154 and travel to the fan blades 120d and the fan blades 120e.

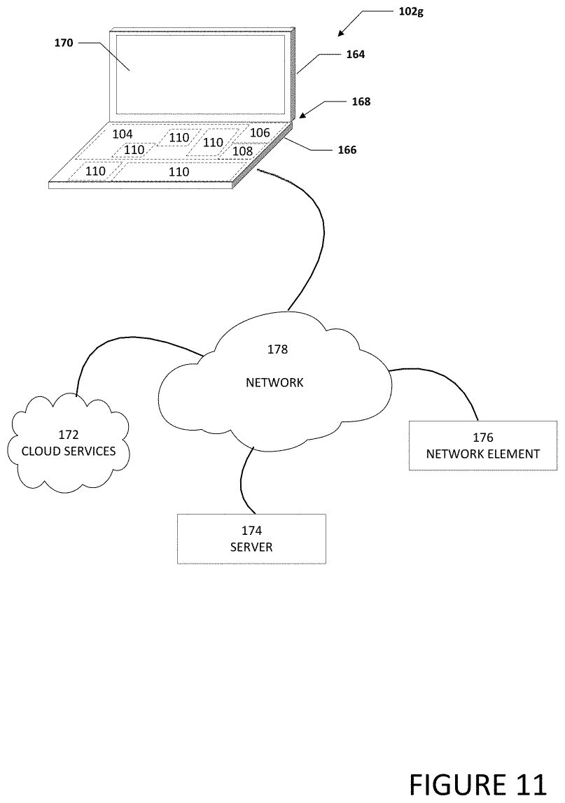

Turning to FIG. 11, FIG. 11 is a simplified block diagram of an electronic device 102g configured with a fan on a PCB, in accordance with an embodiment of the present disclosure. In an example, the electronic device 102g can include a first housing 164 and a second housing 166. The first housing 164 can be rotatably or pivotably coupled to the second housing using a hinge 168. The first housing 164 can include a display 170. The second housing 166 can include the support structure 104, the air mover 106, the air mover controller 108, and one or more electronic components 110.

Each of the one or more electronic components 110 may be a heat generating device (e.g., processor, logic unit, field programmable gate array (FPGA), chip set, integrated circuit (IC), a graphics processor, graphics card, battery, memory, or some other type of heat generating device). The support structure 104 can be a substrate such as a non-semiconductor substrate or a semiconductor substrate and more particularly, a PCB. In one implementation, the non-semiconductor substrate may be silicon dioxide, an inter-layer dielectric composed of silicon dioxide, silicon nitride, titanium oxide and other transition metal oxides. Although a few examples of materials from which the non-semiconducting substrate may be formed are described here, any material that may serve as a foundation upon which a non-semiconductor device may be built falls within the spirit and scope of the embodiments disclosed herein.

In another implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and molybdenum disulphide, organic materials such as pentacene, transparent oxides such as indium gallium zinc oxide poly/amorphous (low temperature of dep) III-V semiconductors and germanium/silicon, and other non-silicon flexible substrates. Although a few examples of materials from which the substrate may be formed are described here, any material that may serve as a foundation upon which a semiconductor device may be built falls within the spirit and scope of the embodiments disclosed herein.

The electronic device 102g (and the electronic devices 102 and 102a-102f) may be in communication with cloud services 172, one or more servers 174, and/or one or more network elements 176 using a network 178. In some examples, the electronic device 102g (and the electronic devices 102 and 102a-102f) may be a standalone device and not connected to the network 178 or another device

Elements of FIG. 11 may be coupled to one another through one or more interfaces employing any suitable connections (wired or wireless), which provide viable pathways for network (e.g., the network 178, etc.) communications. Additionally, any one or more of these elements of FIG. 11 may be combined or removed from the architecture based on particular configuration needs. The network 178 may include a configuration capable of transmission control protocol/Internet protocol (TCP/IP) communications for the transmission or reception of packets in a network. The electronic devices 102 and 102a-102g may also operate in conjunction with a user datagram protocol/IP (UDP/IP) or any other suitable protocol where appropriate and based on particular needs.

Turning to the infrastructure of FIG. 11, the network 178 represents a series of points or nodes of interconnected communication paths for receiving and transmitting packets of information. The network 178 offers a communicative interface between nodes, and may be configured as any local area network (LAN), virtual local area network (VLAN), wide area network (WAN), wireless local area network (WLAN), metropolitan area network (MAN), Intranet, Extranet, virtual private network (VPN), and any other appropriate architecture or system that facilitates communications in a network environment, or any suitable combination thereof, including wired and/or wireless communication.

In the network 178, network traffic, which is inclusive of packets, frames, signals, data, etc., can be sent and received according to any suitable communication messaging protocols. Suitable communication messaging protocols can include a multi-layered scheme such as Open Systems Interconnection (OSI) model, or any derivations or variants thereof (e.g., Transmission Control Protocol/Internet Protocol (TCP/IP), user datagram protocol/IP (UDP/IP)). Messages through the network could be made in accordance with various network protocols, (e.g., Ethernet, Infiniband, OmniPath, etc.). Additionally, radio signal communications over a cellular network may also be provided. Suitable interfaces and infrastructure may be provided to enable communication with the cellular network.

The term “packet” as used herein, refers to a unit of data that can be routed between a source node and a destination node on a packet switched network. A packet includes a source network address and a destination network address. These network addresses can be Internet Protocol (IP) addresses in a TCP/IP messaging protocol. The term “data” as used herein, refers to any type of binary, numeric, voice, video, textual, or script data, or any type of source or object code, or any other suitable information in any appropriate format that may be communicated from one point to another in electronic devices and/or networks.

Although the present disclosure has been described in detail with reference to particular arrangements and configurations, these example configurations and arrangements may be changed significantly without departing from the scope of the present disclosure. Moreover, certain components may be combined, separated, eliminated, or added based on particular needs and implementations. Additionally, although the electronic devices 102 and 102a-102g have been illustrated with reference to particular elements and operations, these elements and operations may be replaced by any suitable architecture, protocols, and/or processes that achieve the intended functionality of the electronic devices 102 and 102a-102g.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

### OTHER NOTES AND EXAMPLES

In Example A1, an electronic device can include a motherboard, where the motherboard includes a first side and an opposite second side, a first air mover coupled to the first side of the motherboard, where a motor of the first air mover is on the motherboard, and an air mover controller, where the air mover controller controls the first air mover through air mover trace in the motherboard.

In Example A2, the subject matter of Example A1 can optionally include where component trace on the motherboard extends under blades of the first air mover.

In Example A3, the subject matter of Example A1 can optionally include input/output ports located on the second side of the motherboard, under the first air mover.

In Example A4, the subject matter of Example A1 can optionally include a second air mover coupled to the second side of the motherboard, under the first air mover, where a motor of the second air mover is on the second side of the motherboard.

In Example A5, the subject matter of Example A4 can optionally include the first air mover and the second air mover are independently controlled by the air mover controller.

In Example A6, the subject matter of Example A4 can optionally include where exhaust air from the first air mover travels away from electronic components in the electronic device and exhaust air from the second air mover travels towards the electronic components in the electronic device.

In Example A7, the subject matter of Example A4 can optionally include where one or more of a height, a length, and a width of the first air mover is different than a height, a length, and a width of the second air mover.

In Example A8, the subject matter of Example A1 can optionally include a casing around a portion of the first air mover, where the air mover controller is located outside of the casing.

In Example A9, the subject matter of Example A1 can optionally include where the motherboard does not include any fan cutouts.

In Example A10, the subject matter of any of Examples A1-A2 can optionally include input/output ports located on the second side of the motherboard, under the first air mover.

In Example A11, the subject matter of any of Examples A1-A3 can optionally include a second air mover coupled to the second side of the motherboard, under the first air mover, where a motor of the second air mover is on the second side of the motherboard.

In Example A12, the subject matter of any of Examples A1-A4 can optionally include the first air mover and the second air mover are independently controlled by the air mover controller.

In Example A13, the subject matter of any of Examples A1-A5 can optionally include where exhaust air from the first air mover travels away from electronic components in the electronic device and exhaust air from the second air mover travels towards the electronic components in the electronic device.

In Example A14, the subject matter of any of Examples A1-A6 can optionally include where one or more of a height, a length, and a width of the first air mover is different than a height, a length, and a width of the second air mover.

In Example A15, the subject matter of any of Examples A1-A7 can optionally include a casing around a portion of the first air mover, where the air mover controller is located outside of the casing.

In Example A16, the subject matter of any of Examples A1-A8 can optionally include where the motherboard does not include any fan cutouts.

Example AA1 is a device including a main printed circuit board for the device, where the main printed circuit board includes a first side and an opposite second side, a central processing unit for the device on the main printed circuit board, and a first air mover coupled to the first side of the main printed circuit board, where a motor of the first air mover is on the main printed circuit board.

In Example AA2, the subject matter of Example AA1 can optionally include an air mover controller, where the air mover controller controls the first air mover through air mover trace in the main printed circuit board.

In Example AA3, the subject matter of Example AA1 can optionally include input/output ports located on the second side of the main printed circuit board, under the first air mover.

In Example AA4, the subject matter of Example AA1 can optionally include a second air mover coupled to the second side of the main printed circuit board, under the first air mover, where a motor of the second air mover is on the second side of the main printed circuit board.

In Example AA5, the subject matter of Example AA4 can optionally include an air mover controller, where the first air mover and the second air mover are independently controlled by the air mover controller using trace in the main printed circuit board.

In Example AA6, the subject matter of Example AA1 can optionally include where component trace on the main printed circuit board extends under blades of the first air mover.

In Example AA7, the subject matter of any of Examples AA1-AA2 can optionally include input/output ports located on the second side of the main printed circuit board, under the first air mover.

In Example AA8, the subject matter of any of Examples AA1-AA3 can optionally include a second air mover coupled to the second side of the main printed circuit board, under the first air mover, where a motor of the second air mover is on the second side of the main printed circuit board.

In Example AA9, the subject matter of any of Examples AA1-AA4 can optionally include an air mover controller, where the first air mover and the second air mover are independently controlled by the air mover controller using trace in the main printed circuit board.

In Example AA10, the subject matter of any of Examples AA1-AA5 can optionally include where component trace on the main printed circuit board extends under blades of the first air mover.

Example M1 is a method including coupling a first air mover to a first side of a motherboard, coupling a motor of the first air mover to a first portion of air mover trace in the motherboard, and coupling an air mover controller to the air mover trace in the motherboard.

In Example M2, the subject matter of Example M1 can optionally include coupling a second air mover to a second side of the motherboard, where the second side of the motherboard is opposite the first side of the motherboard and coupling the second air mover to a second portion of air mover trace in the motherboard.

In Example M3, the subject matter of Example M2 can optionally include where the air mover controller independently controls the first air mover through the first portion of air mover trace in the motherboard and the second air mover through the second portion of air mover trace in the motherboard.

In Example M4, the subject matter of Example M1 can optionally include where input/output ports are located on a second side of the motherboard, under the first air mover, where the second side of the motherboard is opposite the first side of the motherboard.

In Example M5, the subject matter of Example M1 can optionally include where component trace on the motherboard extends under blades of the first air mover.

In Example M6, the subject matter of any of the Examples M1-M2 can optionally include where the air mover controller independently controls the first air mover through the first portion of air mover trace in the motherboard and the second air mover through the second portion of air mover trace in the motherboard.

In Example M7, the subject matter of any of the Examples M1-M3 can optionally include where input/output ports are located on a second side of the motherboard, under the first air mover, where the second side of the motherboard is opposite the first side of the motherboard.

In Example M8, the subject matter of any of the Examples M1-M4 can optionally include where component trace on the motherboard extends under blades of the first air mover.

What is claimed is:

1. An electronic device comprising:
a motherboard, wherein the motherboard includes a first side and an opposite second side;
a first air mover coupled to the first side of the motherboard, wherein a motor of the first air mover is on the motherboard; and
an air mover controller, wherein the air mover controller controls the first air mover through air mover trace in the motherboard.

2. The electronic device of claim 1, wherein component trace on the motherboard extends under blades of the first air mover.

3. The electronic device of claim 1, further comprising:
input/output ports located on the second side of the motherboard, under the first air mover.

4. The electronic device of claim 1, further comprising:
a second air mover coupled to the second side of the motherboard, under the first air mover, wherein a motor of the second air mover is on the second side of the motherboard.

5. The electronic device of claim 4, wherein the first air mover and the second air mover are independently controlled by the air mover controller.

6. The electronic device of claim 4, wherein exhaust air from the first air mover travels away from electronic components in the electronic device and exhaust air from the second air mover travels towards the electronic components in the electronic device.

7. The electronic device of claim 4, wherein one or more of a height, a length, and a width of the first air mover is different than a height, a length, and a width of the second air mover.

8. The electronic device of claim 1, further comprising:
a casing around a portion of the first air mover, wherein the air mover controller is located outside of the casing.

9. The electronic device of claim 1, wherein the motherboard does not include any fan cutouts.

10. A device comprising:
a main printed circuit board for the device, wherein the main printed circuit board includes a first side and an opposite second side;
a central processing unit for the device on the main printed circuit board; and
a first air mover coupled to the first side of the main printed circuit board, wherein a motor of the first air mover is on the main printed circuit board.

11. The device of claim 10, further comprising:
an air mover controller, wherein the air mover controller controls the first air mover through air mover trace in the main printed circuit board.

12. The device of claim 10, further comprising:
input/output ports located on the second side of the main printed circuit board, under the first air mover.

13. The device of claim 10, further comprising:
a second air mover coupled to the second side of the main printed circuit board, under the first air mover, wherein a motor of the second air mover is on the second side of the main printed circuit board.

14. The device of claim 13, further comprising:
an air mover controller, wherein the first air mover and the second air mover are independently controlled by the air mover controller using trace in the main printed circuit board.

15. The device of claim 10, wherein component trace on the main printed circuit board extends under blades of the first air mover.

16. A method comprising:
coupling a first air mover to a first side of a motherboard;
coupling a motor of the first air mover to a first portion of air mover trace in the motherboard; and
coupling an air mover controller to the air mover trace in the motherboard.

17. The method of claim 16, further comprising:
coupling a second air mover to a second side of the motherboard, wherein the second side of the motherboard is opposite the first side of the motherboard; and
coupling the second air mover to a second portion of air mover trace in the motherboard.

18. The method of claim 17, wherein the air mover controller independently controls the first air mover through the first portion of air mover trace in the motherboard and the second air mover through the second portion of air mover trace in the motherboard.

19. The method of claim 16, wherein input/output ports are located on a second side of the motherboard, under the first air mover, wherein the second side of the motherboard is opposite the first side of the motherboard.

20. The method of claim 16, wherein component trace on the motherboard extends under blades of the first air mover.
